(19) United States
(12) Patent Application Publication
(10) Pub. No.: US 2008/0205115 A1
(43) Pub. Date: Aug. 28, 2008

(54) APPARATUS AND METHOD FOR TRIMMING INTEGRATED CIRCUIT

(75) Inventors: Chien-Hung Ho, Hsinchu City (TW); Yu WU, Taipei County (TW)

Correspondence Address: J C PATENTS, INC., 4 VENTURE, SUITE 250, IRVINE, CA, 92618, US

(73) Assignee: EMEMORY TECHNOLOGY INC., Hsin-Chu (TW)

(21) Appl. No.: 11/836,362

(22) Filed: Aug. 9, 2007

(30) Foreign Application Priority Data
Feb. 27, 2007 (TW) 96106814

(51) Int. Cl. G11C 17/00

(52) U.S. Cl. 365/94

(57) ABSTRACT

A trimming apparatus including a switch transistor and a one-time programming (OTP) memory component is provided. The switch transistor has a first source/drain terminal connected to a first bias voltage, a gate terminal used for receiving a switch signal, and a second source/drain terminal connected to a first source/drain terminal of the OTP memory component. When the trimming apparatus provided by the present invention intends to perform trimming for an integrated circuit, the switch transistor is conducted to program the OTP memory component.

### CROSS-REFERENCE TO RELATED APPLICATION

This application claims the priority benefit of Taiwan application serial no. 96106814, filed Feb. 27, 2007. All disclosure of the Taiwan application is incorporated herein by reference.

### BACKGROUND OF THE INVENTION

1. Field of the Invention

The present invention relates to a trimming apparatus. More particularly, the present invention relates to a trimming apparatus using a one-time programming (OTP) memory component.

2. Description of Related Art

During the fabricating process of an integrated circuit (IC), electrical characteristics may drift due to the process. The output voltage is originally intended to be 1.2V, but finally is measured to be 1.25V or 1.15V. The drift of electrical characteristics causes uncertainties in designing circuit. Therefore, in order to eliminate factors causing electrical drift, besides the continuous progress on the manufacturing process of IC, a trimming step can be adopted to adjust the drifted electrical characteristics.

The conventional trimming technique includes a poly fuse method or a laser cut method. In the conventional art, one trimming circuit is connected to a main circuit of the IC, for example, a metal is used for burnt down material in the laser cut technique. When the electrical characteristics of the IC must be adjusted, the circuit structure can be changed only by burning down the connecting metal, so that the electrical characteristics of the IC can be changed to obtain the desired values. The poly fuse method is similar to the above, but uses the poly silicon instead of the metal and a large current instead of the laser, so the electrical characteristics of the IC are still changed.

However, the conventional technique has the following disadvantages.

1. If the IC is packaged, trimming can not be performed for the IC according to the laser cut technique.
2. According to the poly fuse trimming technique, although the trimming can be performed for the packaged circuit, the trimming failure rate is extremely high, thereby the yield is reduced.
3. Moreover, the laser cut technique further needs additional equipment to perform trimming for the IC, and thus the hardware cost is increased.

### SUMMARY OF THE INVENTION

Therefore, the present invention provides a trimming apparatus, capable of performing trimming after the IC is packaged.

The present invention also provides an IC, for which the trimming can be performed without using additional equipments.

The present invention further provides a trimming method, using simple operations to perform trimming for the circuit.

The trimming apparatus provided by the present invention includes a one-time programming (OTP) memory component. When the trimming apparatus provided by the present invention intends to perform trimming for a circuit, the OTP memory component is programmed. In the present invention, the OTP memory component is with single poly.

In the embodiment of the present invention, the trimming apparatus further includes a programming circuit and a reading circuit. The programming circuit programs the OTP memory component through a second source/drain terminal of the OTP memory component. Moreover, the reading circuit senses the cell current of the OTP memory component according to the state of the OTP memory.

From another point of view, the present invention provides a circuit trimming method, which includes providing an OTP memory component with single poly as the circuit trimming apparatus. When the circuit has defects, the OTP memory component is programmed to switch an operating state of the circuit. Relatively, when the circuit operates normally, the state of the OTP memory component is maintained.

Since the present invention changes the electrical characteristics of the circuit through programming the OTP memory component, the present invention can still perform trimming for the IC after the IC is packaged. Moreover, since the present invention performs trimming for the circuit by programming the OTP memory component, additional equipments are not needed.

In order to make the aforementioned and other objectives, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a circuit diagram of a trimming apparatus according to a preferred embodiment of the present invention.

FIG. 2 is a circuit diagram of a programming circuit according to a preferred embodiment of the present invention.

FIG. 3 is an internal block diagram of a memory of the trimming apparatus of the present invention.

### DESCRIPTION OF EMBODIMENTS

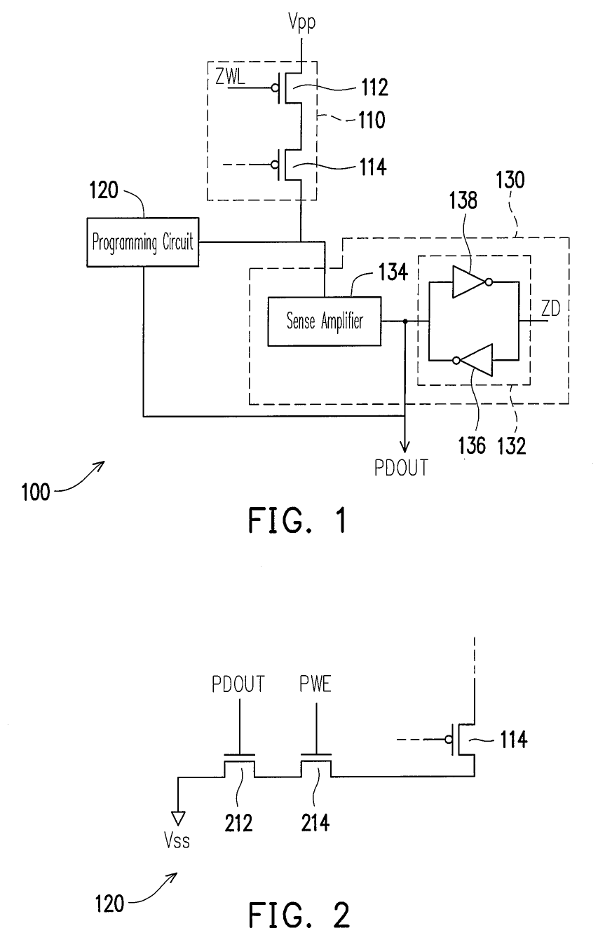

FIG. 1 is a circuit diagram of a trimming apparatus according to a preferred embodiment of the present invention. Referring to FIG. 1, the trimming apparatus 100 provided by the present invention includes a memory unit 110, a programming circuit 120, and a reading circuit 130.

The memory unit 110 includes a switch transistor 112 and an OTP memory component 114 with single poly. In this embodiment, the switch transistor 112 is realized by a PMOS transistor, which has a source/drain terminal coupled to a bias voltage Vpp, a gate terminal used for receiving a switch signal ZWL; and a second source/drain terminal coupled to a first source/drain terminal of the OTP memory component 114.

In this embodiment, the OTP memory component 114 is realized by a PMOS memory component with single poly, which has a floating gate for storing a hot carrier produced after the programming of the OTP memory component 114. The first source/drain terminal of the OTP memory component 114 is coupled to the second source/drain terminal of the switch transistor 112, and the second source/drain terminal of the OTP memory component 114 is coupled to the programming circuit 120 and the reading circuit 130. Thereby, the programming circuit 120 programs the OTP memory component 114 through the second source/drain terminal of the OTP memory component 114.

FIG. 2 is a circuit diagram of a programming circuit according to a preferred embodiment of the present invention. Referring to FIG. 2, the programming circuit 120 is realized by two transistors 212 and 214. In this embodiment, the transistors 212 and 214 are NMOS transistors. The transistor 212 has a first source/drain terminal connected to a bias voltage Vss, a gate terminal used for receiving the trimming output signal PDOUT stored by the latch 132, and a second source/drain terminal connected to the first source/drain terminal of the transistor 214.

Moreover, the gate terminal of the transistor 214 receives a programming control signal PWE, and the second source/drain terminal of the transistor 214 is connected to the second source/drain terminal of the OTP memory component 114. When the OTP memory component 114 is to be programmed, the latch 132 makes a trimming output signal PDOUT at a high level state, and the programming control signal PWE is also enabled at a high level state. Meanwhile, the transistors 212 and 214 are both conducted, so that the OTP memory component 114 is programmed. In other words, the hot carrier is stored at the floating gate of the OTP memory component 114.

Referring to FIG. 1, the reading circuit 130 includes a latch 132 and a sense amplifier 134, and the latch 132 includes inverters 136 and 138. The inverter 136 receives a signal ZD, and generates a trimming output signal PDOUT to the programming circuit 120. Moreover, an input terminal of the inverter 138 is connected to an output terminal of the inverter 136, and an output terminal of the inverter 138 is coupled to an input terminal of the inverter 136.

When the OTP memory component 114 is not programmed, the OTP memory component 114 generates a cell current I1. Otherwise, if the OTP memory component 114 is programmed, a cell current I2 is generated. The sense amplifier 134 is used to sense the cell current of the OTP memory component 114 to produce different logical output levels. So that the trimming apparatus 100 can be applied in many ICs. For example, in the design of an analog IC, due to the process, some operating parameters such as operating voltages or operating currents will drift. By using the trimming apparatus provided by the present invention, the electrical characteristics of IC can be adjusted through different cell currents.

If in an IC, an output voltage of a certain main circuit is set to be 1.6 V. In the process, the IC can be tested at a test machine. If a measurement result indicates that the operating parameters of the main circuit do not change, i.e., the output voltage remains 1.6 V, and thus the state of the OTP memory component 114 in the present invention is maintained to produce the cell current I1. When the sense amplifier 134 senses the cell current I1 of the OTP memory component 114, the output voltage of the main circuit is maintained to be 1.6 V. Contrarily, if the electrical characteristics of the main circuit drift, the output voltage changes to be, for example, 1.8 V. At this time, the cell current I2 is generated from programming the above OTP memory component 114. When the sense amplifier 134 senses the cell current I2 of the OTP memory component 114, the output voltage of the main circuit is adjusted to be 1.6 V.

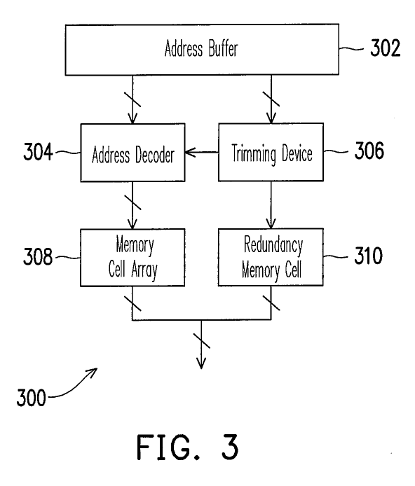

The trimming apparatus provided by the present invention can also be applied to the memory. FIG. 3 is an internal block diagram of a memory of the trimming apparatus of the present invention. Referring to FIG. 3, the memory 300 can also be a non-volatile memory, for example, a dynamic random access memory (DRAM), a static random access memory (SRAM), or a flash memory, etc.

The memory 300 includes an address buffer 302, an address decoder 304, a trimming apparatus 306, a memory cell array 308, and a redundancy memory cell 310. The address buffer 302 is used to receive a plurality of address data, and the output is coupled to the address decoder 304 and the trimming apparatus 306. After the address decoder 304 decodes the output of the address buffer 302, a decoded data is produced, and transferred to the memory cell array 308 for accessing.

When the memory cell in the memory cell array 308 has defects and cannot operate normally, the trimming apparatus 306 outputs a signal to the address decoder 304, so as to disenable the memory cell that does not operate normally. The internal structure of the trimming apparatus 306 is similar to that of the trimming apparatus 100, which can have a plurality of OTP memory components. Therefore, the present invention can disenable the memory cells which cannot operate normally by programming the sensing current produced by the OTP memory component.

Besides disenabling the memory cells that cannot operate normally, the trimming apparatus 306 also outputs a sensing current signal to enable the redundancy memory cell 310, so as to replace the memory cells that cannot operate normally in the memory cell array 308.

In view of the above, the present invention at least has the follow advantages.

1. Since the present invention performs trimming by programming the OTP memory component, the present invention does not need additional equipments, thus reducing cost of hardware.
2. Since the present invention performs trimming by programming the OTP memory component, the present invention can also perform trimming for IC after the IC is packaged.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A trimming apparatus, comprising:
a one-time programming (OTP) memory component with single poly structure, wherein when the trimming apparatus performs trimming on a circuit, the OTP memory component is programmed: and
a switch transistor having a first source/drain terminal connected to a first bias voltage, a gate terminal used for receiving a switch signal, and a second source/drain terminal connected to a first source/drain terminal of the OTP memory component.

2. The trimming apparatus as claimed in claim 1, wherein the switch transistor is a PMOS transistor.

3. The trimming apparatus as claimed in claim 1, wherein the OTP memory component is a PMOS memory component.

4. The trimming apparatus as claimed in claim 1, further comprising:
a programming circuit, programming the OTP memory component through a second source/drain terminal of the OTP memory component; and
a reading circuit, sensing an output current of the OTP memory component according to a state of the OTP memory component.

5. The trimming apparatus as claimed in claim 4, wherein the programming circuit comprises:
a first NMOS transistor, having a first source/drain terminal connected to a second bias voltage, a gate terminal connected to the reading circuit for receiving a trimming signal; and
a second NMOS transistor, having a first source/drain terminal connected to a second source/drain terminal of the first NMOS transistor, a gate terminal used for receiving a programming control signal, and a second source/drain terminal coupled to a second source/drain terminal of the OTP memory component.

6. The trimming apparatus as claimed in claim 4, wherein the reading circuit comprises:
a sense amplifier, coupled to the second source/drain terminal of the OTP memory component for sensing the output current of the OTP memory component; and
a latch, for outputting a trimming output signal to the sense amplifier and the programming circuit.

7. The trimming apparatus as claimed in claim 6, wherein the latch comprises:
a first inverter, for outputting the trimming output signal; and
a second inverter, having an output terminal and an input terminal connected to the input terminal and the output terminal of the first inverter.

8. A trimming method for a circuit, comprising:
providing a one-time programming (OTP) memory component with single poly structure used as a circuit trimming apparatus;
when the circuit has defect, programming the OTP memory component to switch an operating state of the circuit; and
when the circuit operates normally, maintaining the state of the OTP memory component.

9. The circuit trimming method as claimed in claim 8, wherein the circuit comprises a memory cell array arranged in a memory device.

10. The circuit trimming method as claimed in claim 9, wherein the memory device comprises a non-volatile memory.

11. The circuit trimming method as claimed in claim 9, wherein the step of switching the circuit state comprises:
programming the OTP memory component to disenable defective memory cells in the memory cell array; and
enabling a plurality of redundancy memory cells to replace the defective memory cells.

12. The circuit trimming method as claimed in claim 9, wherein the memory device is a dynamic random access memory.

13. The circuit trimming method as claimed in claim 9, wherein the memory device is a static random access memory.

14. The circuit trimming method as claimed in claim 9, wherein the memory device is a flash memory.

15. The circuit trimming method as claimed in claim 8, wherein the circuit is an analog integrated circuit (IC).

16. The circuit trimming method as claimed in claim 8, wherein the step of switching the circuit state comprises programming the OTP memory component to trim an operating parameter of the circuit.

17. The circuit trimming method as claimed in claim 16, wherein the operating parameter comprises an operating voltage or an operating current.
